(19) United States
(12) Patent Application Publication
(10) Pub. No.: US 2025/0055425 A1
(43) Pub. Date: Feb. 13, 2025

(54) Radio-frequency Amplifier with Supply and Load Modulation

(71) Applicant: Apple Inc., Cupertino, CA (US)

(72) Inventors: Stephan Henzler, Munich (DE); Andreas Langer, Munich (DE)

(21) Appl. No.: 18/672,498

(22) Filed: May 23, 2024

Related U.S. Application Data
(60) Provisional application No. 63/518,193, filed on Aug. 8, 2023.

(51) Int. Cl. H03F 3/189; H03F 1/02; H03G 3/00; H04B 1/04

(52) U.S. Cl. CPC H03F 3/189; H03F 1/0222; H03G 3/004; H04B 1/04; H03F 2200/102; H03F 2200/451; H04B 2001/045

(57) ABSTRACT

An electronic device may include wireless circuitry. The wireless circuitry may include a radio-frequency amplifier having a data input configured to receive a radio-frequency signal generated from a baseband signal, supply modulation blocks configured to output a power supply voltage, derived from the baseband signal, for powering the radio-frequency amplifier, and load modulation blocks configured to output a load control signal, derived from the baseband signal and a bandwidth reduced envelope signal output from the supply modulation circuitry, for tuning an adjustable load component of the radio-frequency amplifier. The supply modulation blocks can include a full envelope generator, a bandwidth reduction block for outputting the bandwidth reduced envelope signal, an envelope shaping block, and an envelope tracker. The load modulation blocks can include an inverse amplifier gain model and a load shaping block.

This application claims the benefit of U.S. Provisional Patent Application No. 63/518,193, filed Aug. 8, 2023, which is hereby incorporated by reference herein in its entirety.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. It can be challenging to design a satisfactory power amplifier for an electronic device.

### SUMMARY

An electronic device may include wireless communications circuitry. The wireless communications circuitry may include one or more processors or signal processing blocks for generating baseband signals, a transceiver for receiving the digital signals and for generating corresponding radio-frequency signals, and one or more radio-frequency power amplifiers configured to amplify the radio-frequency signals for transmission by one or more antennas in the electronic device. At least one of the radio-frequency power amplifiers can be implemented as a load modulated radio-frequency amplifier circuit. The load modulated radio-frequency amplifier circuit can include an amplifier core coupled to an adjustable load impedance. Such type of amplifier circuit can also be referred to as a load-line modulated radio-frequency power amplifier.

As aspect of the disclosure provides wireless circuitry that includes wireless circuitry having a radio-frequency amplifier configured to receive a radio-frequency signal generated from a baseband signal, supply modulation circuitry configured to output a power supply voltage, derived from the baseband signal, for powering the radio-frequency amplifier, and load modulation circuitry configured to output a load (load-line) control signal, derived from the baseband signal and an envelope signal output from the supply modulation circuitry, for tuning an adjustable load component of the radio-frequency amplifier. The supply modulation circuitry can include a first envelope generator configured to receive the baseband signal and to output a corresponding target envelope signal having a first bandwidth, a second envelope generator configured to receive the target envelope signal and to output the envelope signal having a second bandwidth less than the first bandwidth of the target envelope signal, an envelope shaping circuit configured to receive the envelope signal from the second envelope generator and to map the received envelope signal to a corresponding envelope tracking control signal, and an envelope tracking circuit configured to receive the envelope tracking control signal from the envelope shaping circuit and to output the power supply voltage to a power supply terminal of the radio-frequency amplifier. The load modulation circuitry can be configured to generate a target load signal based on an inverse amplifier gain model that is a function of the baseband signal and the envelope signal and can include a load shaping circuit configured to receive the target load signal and to generate the load control signal based on the received target load signal.

An aspect of the disclosure provides a method of operating wireless circuitry that includes using a radio-frequency amplifier to receive a radio-frequency signal generated from a baseband signal, using supply modulation circuitry to output an envelope signal and to output a power supply voltage that is derived from the baseband signal to a power supply terminal of the radio-frequency amplifier, using load modulation circuitry to output a load control signal that is derived from the baseband signal and the envelope signal, and tuning an adjustable load component of the radio-frequency amplifier with the load control signal. The method can further include generating a target envelope signal from the baseband signal, where the target envelope signal has a first bandwidth and where the envelope signal has a second bandwidth less than the first bandwidth, generating an envelope tracking control signal from the envelope signal, and generating the power supply voltage as a function of the envelope tracking control signal. The method can further include generating a target load signal based on an inverse amplifier gain model that is a function of the baseband signal and the envelope signal, generating the load control signal as a function of the target load signal, and maximizing the envelope signal while ensuring that the target load signal does not saturate the load shaping block.

An aspect of the disclosure provides wireless circuitry that includes a radio-frequency amplifier configured to receive a radio-frequency signal generated from a baseband signal, a first envelope generation block configured to receive the baseband signal and to output a first envelope signal having a first bandwidth, and a second envelope generation block configured to receive the first envelope signal and to output a second envelope signal having a second bandwidth different than the first bandwidth. The second envelope generation block can include a bandwidth reduction block configured to output the second envelope signal such that the second bandwidth of the second envelope signal is less than the first bandwidth of the first envelope signal.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having amplifiers in accordance with some embodiments.

FIG. 3 is a diagram illustrating how an amplifier gain level can be adjusted using different control knobs such as varying supply voltage levels and varying load line control signals in accordance with some embodiments.

FIG. 4 is a diagram of illustrative wireless circuitry having a load modulated radio-frequency amplifier configured to receive a radio-frequency input signal via a radio-frequency data path, a time-varying power supply voltage via a supply modulation path, and a load control signal via a load modulation path in accordance with some embodiments.

FIG. 5 is a timing diagram showing a temporal behavior of a bandwidth reduced envelope signal in accordance with some embodiments.

FIG. 6 is a flow chart of illustrative steps for operating wireless circuitry of the type shown in connection with FIGS. 1-5 in accordance with some embodiments.

### DETAILED DESCRIPTION

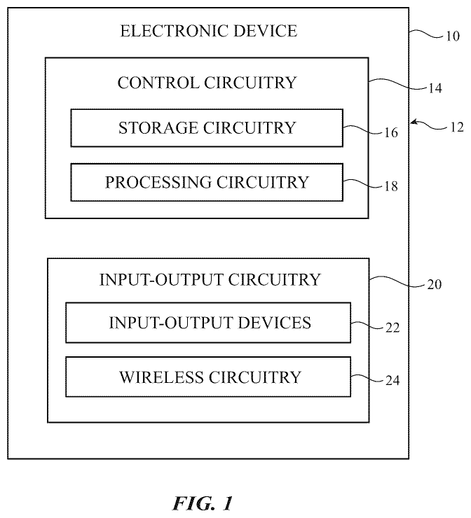

An electronic device such as device 10 of FIG. 1 may be provided with wireless circuitry. The wireless circuitry may include one or more processors for generating a baseband signal that can be conveyed to an antenna through a radio-frequency transmit path. The radio-frequency transmit path can include an upconversion circuit, a power amplifier such as a load modulated amplifier, means for modulation for the load modulated amplifier, and means for supply voltage modulation having an envelope tracking (ET) circuit for the amplifier. The supply modulation means can include an envelope generation circuit and a bandwidth reduction circuit for outputting a bandwidth reduced envelope signal that varies within an envelope tolerance band of an ideal envelope signal. The load modulation means can include a load shaping circuit for generating a load control signal based on an inverse gain model that is a function of the bandwidth reduced envelope signal.

The supply modulation means and the load modulation means can both be referred to and defined herein as a control signal generator. In other words, the time-varying supply voltage output from the supply modulation means can be referred to as a control signal, and the load control signal output from the load modulation means can also be referred to as a control signal. Configuring and operating the power amplifier in this way can be technically advantageous and beneficial to improve the efficiency of the power amplifier while reducing the bandwidth requirements for the envelope tracking supply modulation operations.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHZ), a 5 GHz WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHZ), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

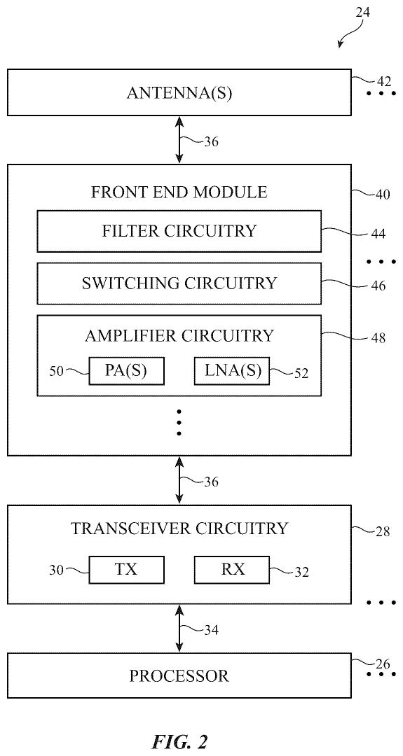

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, power management unit, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHZ), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PA) circuits 50 in the transmit (uplink) path. A power amplifier 50 (sometimes referred to as radio-frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

It can be challenging to design a satisfactory radio-frequency power amplifier for an electronic device. In general, a radio-frequency amplifier is most efficient when it is operating in compression (i.e., when an increase in the input power results in a non-linear change in the output power of the amplifier, which typically occurs at the higher range of input power levels). Conventional radio-frequency power amplifiers that receive a fixed power supply voltage will become less efficient when the amplifier operates at lower input power levels.

In an effort to address this reduction in efficiency, an envelope tracking (ET) technique has been developed where the power supply voltage of the radio-frequency power amplifier is continuously adjusted such that the gain of the power amplifier remains constant over varying signal amplitudes (sometimes referred to as iso-gain operation). Other gain shaping strategies such as iso-compression operation, pre-defined gain-over-power characteristic, etc. are possible as well. As an example, an envelope tracking system can generate a variable power supply voltage using a static linear transformation of the absolute value of a baseband signal from which the radio-frequency signals are generated. Conventional envelope tracking techniques, however, reach a feasibility limit at around 200 MHz signal bandwidth.

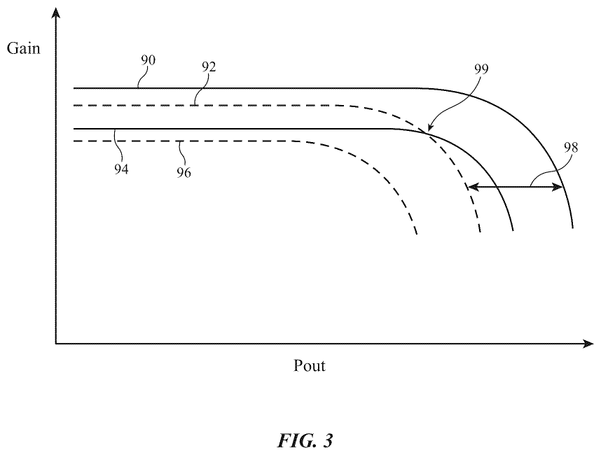

In certain applications, the radio-frequency power amplifier can be implemented as a load modulated radio-frequency power amplifier. A load modulated radio-frequency power amplifier has an adjustable load component (including an adjustable load line) that can be tuned to provide different gain profiles. Load modulation for a radio-frequency amplifier can provide highly efficient transmit operation but can exhibit a fairly limited tuning range. This is illustrated in FIG. 3. Curve 90 may represent the amplifier gain as a function of the amplifier output power Pout when a small (e.g., lower limit) load value is present, whereas curve 92 may represent the amplifier gain as a function of Pout when a large (e.g., upper limit) load value is present. Amplifier gain can be inversely proportional to the load value (e.g., a high load value will decrease the gain, whereas a low load value will increase the gain). As shown in FIG. 3, tuning the adjustable load of the load modulated amplifier can only provide a fairly limited output power tuning range (as shown by arrow 98) of 5 dB or less, as an example.

Curves 90 and 92 may both correspond to the scenario where a high (e.g., upper limit) supply voltage is provided to the power amplifier. In accordance with an embodiment, the amplifier gain can be tuned by simultaneously adjusting the load and adjusting the supply voltage (e.g., via envelope tracking techniques). Curves 94 and 96 show the amplifier gain profile when a low (e.g., lower limit) supply voltage is provided to the power amplifier. In particular, curve 94 may represent the amplifier gain profile as a function of Pout when a small load value is present, whereas curve 96 may represent the amplifier gain profile as a function of Pout when a large load value is present. Thus, lowering the supply voltage of the amplifier can help provided an extended output power tuning range between curves 94 and 96. Here, tuning both the amplifier supply voltage and the load can add redundancy to the tuning options/flexibility, which can be helpful to alleviate other design constraints. For example, a less accurate (more coarse) envelope tracking can be used, which allows for a lower power supply tracking bandwidth, and any gap in the target gain can be filled or achieved via the load modulation. A lower supply bandwidth requirement can be technically advantageous and beneficial to improve the efficiency of the overall radio-frequency amplifier.

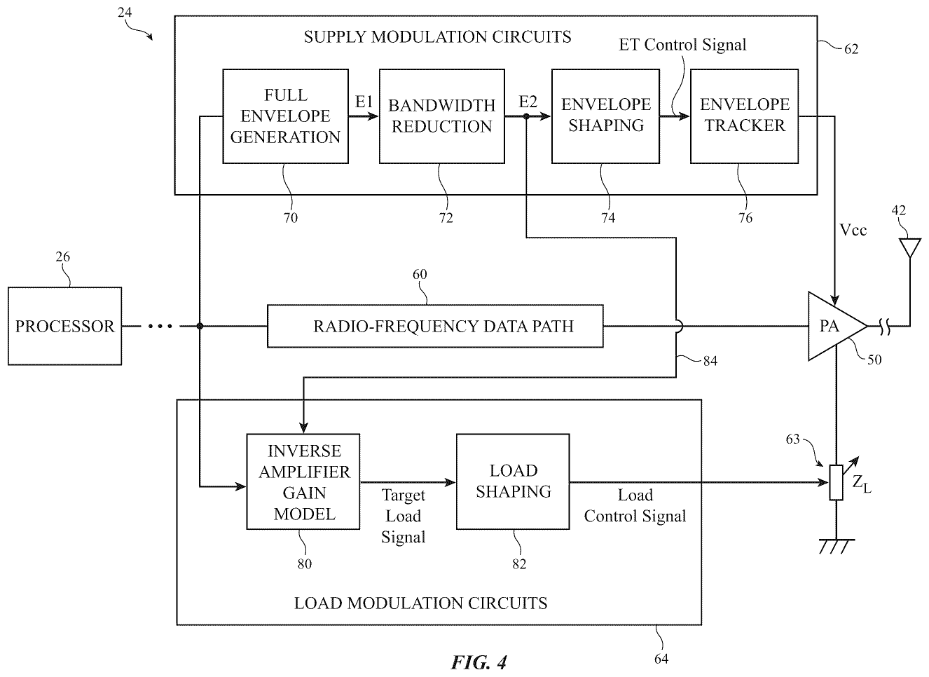

FIG. 4 is a diagram of illustrative wireless circuitry 24 having a load modulated radio-frequency amplifier 50 configured to receive a radio-frequency input signal via a radio-frequency data path 60, a time-varying power supply voltage Vcc via a supply modulation path, and a load control signal via a load modulation path in accordance with some embodiments. Radio-frequency data path 60 may receive a baseband signal from processor 26. Processor 26 may be considered part of wireless circuitry 24 or may be considered separate from wireless circuitry 24. Processor 26 may represent one or more processors such as a baseband processor, an application processor, a digital signal processor, a microcontroller, a microprocessor, a central processing unit (CPU), a programmable device, a combination of these circuits, and/or one or more processors within circuitry 18. Processor 26 may be configured to generated digital signals, which are sometimes referred to as baseband signals, digital signals, or transmit signals. As examples, the digital signals generated by processor 26 may include in-phase (I) and quadrature-phase (Q) signals, radius and phase signals, or other digitally-coded signals.

The radio-frequency (transmit) data path 60 can include one or more upconversion circuits (e.g., a radio-frequency mixer or modulator for upconverting signals from a baseband frequency range in the range of a couple hundred to a couple thousand Hz to radio frequencies in the range of hundreds of MHz or in the GHz range), a digital predistortion circuit (e.g., a circuit for predistorting baseband signals prior to amplification at amplifier 50), one or more variable gain (digital) amplifiers, a data converter (e.g., a digital-to-analog conversion or “DAC” circuit, a radio-frequency DAC block, etc.), and/or other baseband/intermediate-frequency/radio-frequency transmit circuit components. The signals conveyed through RF data path 60 can be provided to a data input (port) of amplifier 50. Radio-frequency amplifier 50 may have an output port that is coupled to antenna 42. Although not explicitly shown in FIG. 4, one or more additional radio-frequency front end components (e.g., filter, switching, tuning, or matching circuitry) can be coupled to input port and/or output port of amplifier 50.

As shown in FIG. 4, amplifier 50 may have a power supply terminal configured to receive power supply voltage Vcc via supply modulation circuits 62 disposed along the supply modulation path. The power supply terminal of amplifier 50 may sometimes be referred to and defined herein as a “control input” of amplifier 50, and power supply voltage Vcc output from supply modulation circuits 62 can therefore sometimes be referred to as a “control signal” for amplifier 50. The supply modulation circuits 62 can therefore sometimes be referred to collectively as a “control signal generator.”

Amplifier 50 may have an adjustable load component Z_{L} configured to receive a load control signal via one or more load modulation circuits (blocks) 64 disposed along the load modulation path. Terminal 63 of the adjustable load component Z_{L} that receives the load control signal may sometimes also be referred to and defined herein as a “control input” of amplifier 50. As a result, the load control signal output from load modulation circuits 64 can also therefore sometimes be referred to as a “control signal” for amplifier 50. The load modulation circuits 64 can therefore sometimes be referred to collectively as a “control signal generator.” Circuits 62 and 64 can thus generally be referred to as control signal generators.

Supply modulation circuits 62, sometimes referred to as power supply modulation circuitry, can be configured to receive a baseband signal from processor 26 and to continuously adjust supply voltage Vcc that powers RF amplifier 50 to ensure that amplifier 50 is constantly operating at peak efficiency. As shown in FIG. 4, supply modulation circuitry 62 can include a first envelope generation circuit such as full envelope generator 70, a second envelope generation circuit such as a bandwidth reduction circuit 72, an envelope shaping circuit such as envelope shaper 74, and an envelope tracking circuit such as envelope tracker 76. Full envelope generation circuit 70 can include an absolute function generator configured to output a first envelope signal E1 by applying an absolute value function to the received baseband signal and can also include a gain shaping component to ensure iso-gain operation. The first envelope signal E1 is sometimes referred to as a target envelope signal with full bandwidth requirements.

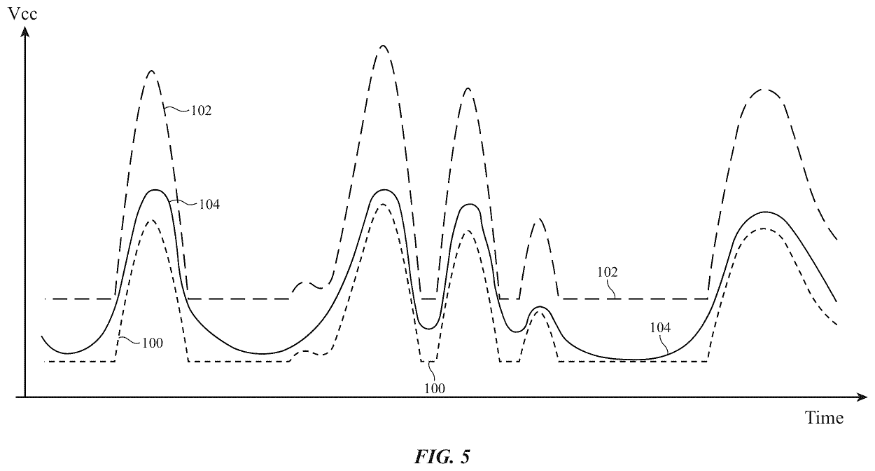

The bandwidth reduction circuit 72 may receive first envelope signal E1 from full envelope generation circuit 70 and output a corresponding second envelope signal E2 having a bandwidth that is smaller than the bandwidth of first (target) envelope signal E1. Signal E2 is therefore sometimes referred to and defined herein as a bandwidth reduced envelope signal. Bandwidth reduction circuit 72 may be configured to maximize the second envelope signal E2 under the constraint that the bandwidth of signal E2 is below the full (maximum) bandwidth of signal E1 and under the constraint that a target load signal in the load modulation path does not saturate load shaping block 82, which will be described in further detail below. This is illustrated in FIG. 5. Line 100 may represent an ideal wideband (full bandwidth) lower envelope limit as a function of time, whereas line 102 represents an ideal wideband (full bandwidth) upper envelope limit as a function of time. The lower bound 100 and upper bound 102 can be generated based on the full bandwidth target envelope signal E1. As shown in FIG. 5, line 104 may represent the second envelope signal E2 as a function of time. Compared to lines 100 and 102, line 104 has reduced bandwidth and is thus more rounded compared to the ideal wideband boundary waveforms. The reduced bandwidth waveform 104 should yield the maximum supply voltage Vcc while fitting within the upper bound 102 and lower bound 100.

Referring back to FIG. 4, the envelope shaping circuit 74 may receive the bandwidth reduced envelope signal E2 and output a corresponding envelope tracking (ET) control signal. For example, envelope shaping circuit 74 may be configured to map signal E2 to an ET control signal (e.g., using a piecewise linear mapping with upper and lower saturation to constrain the highest/lowest voltage Vcc seen by amplifier 50). The desired mapping and determination of the piecewise linear regions can be found via calibration operations in accordance with a certain optimization target. The envelope tracker 76 may receive the ET control signal from envelope shaper 74 and output supply voltage Vcc. Envelope tracker 76 (sometimes referred envelope tracking power management circuit) may be configured to translate the internal algorithmic ET control signal to a physical voltage Vcc that directly powers amplifier 50.

The supply modulation circuitry 62 of FIG. 3 is exemplary. If desired, supply modulation circuitry 62 may optionally include a signal shaping lookup table (LUT) to implement LUT-based shaping functions, linear signal processing blocks to implement linear shaping functions, non-linear signal processing blocks to implement (for example) polynomial shaping functions, equalization blocks, delay adjustment circuits, signal bypass circuitry, dynamic gain adaptation circuitry, compensation circuitry such as temperature compensation circuit, digital-to-analog converters, a combination of these circuits, and/or other signal conditioning circuits.

Load modulation circuits 64, sometimes referred to as load modulation blocks or circuitry, can be configured to receive a baseband signal from processor 26 and to output a corresponding load control signal for adjusting the load modulated amplifier load component Z_{L}. For example, load modulation circuitry 64 may include an absolute value function generator, a signal shaping function, a linear or non-linear transformation function, a combination of these functions, or other signal conditioning function for outputting the load control signal that can help tune load component Z_{L} for optimum performance and efficiency.

In the example of FIG. 4, load modulation circuitry 64 can generate a target load signal based on gain model such as an inverse amplifier gain model 80. In particular, the inverse amplifier gain model 80 may be used to generate a target load signal as a function of the baseband signal received from processor 26 and the second bandwidth reduced envelope signal E2 received via signal path 84 and a gain target value or compression target value for the amplifier. The gain or compression target values can be programmable. The target load signal computed by the inverse amplifier gain model 80 may be dynamically tuned to ensure that the instantaneous amplifier gain is constant when amplifier 50 is operated with the current baseband signal and supplied with voltage Vcc generated based on the current bandwidth reduced envelope signal E2 (e.g., the target load signal can ensure that amplifier 50 is operating in compression mode in a subrange of instantaneous amplifier output power levels). Inverse gain model 80 may therefore also be a function of the target amplifier output power level.

Load modulation circuitry 64 may further include a load shaping circuit such as load shaper 82 configured to receive the target load signal generated based on the inverse amplifier gain model 80 and to output a correspond load control signal as a function of the target load signal. For example, load shaping circuit 82 may be configured to map the internal algorithmic target load signal to a physical load control signal that directly tunes adjustable load Z_{L} (e.g., using a piecewise linear mapping with upper and lower saturation to constrain the highest/lowest load control signal seen by amplifier 50 at terminal 63). The desired mapping and determination of the piecewise linear regions can be found via calibration operations in accordance with a certain optimization target based on amplifier gain, offset, and saturation requirements. If the target load signal is too large, the load control signal output from block 82 can saturate. Bandwidth reduction circuit 72 should be configured to output signal E2 under the constraint that the corresponding target load signal output based on the inverse gain model 80 does not saturate the load shaper 82.

Configuring and operating amplifier 50 using supply modulation circuitry 62 and load modulation circuitry 64 in this way can be technically advantageous and beneficial to improve the efficiency of amplifier 50 while reducing the bandwidth requirements for the envelope tracking supply modulation operations.

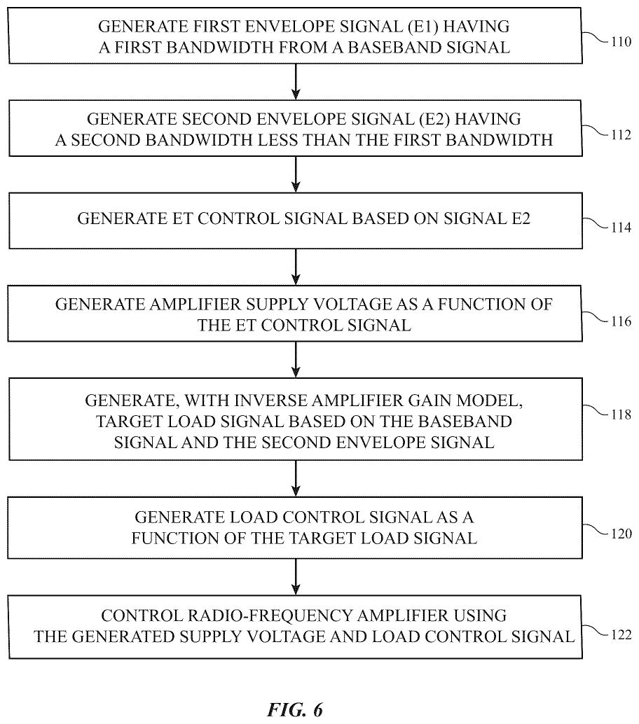

FIG. 6 is a flow chart of illustrative steps for operating wireless circuitry 24 of the type described in connection with FIGS. 1-5. During the operations of block 110, first envelope generation circuit 70 can generate a first envelope signal E1 having a first bandwidth based on a baseband signal output from one or more processor(s) 26. The first envelope signal E1 may have full bandwidth requirements and may sometimes be referred to herein as a target envelope signal.

During the operations of block 112, bandwidth reduction circuit 72 can generate a second envelope signal E2 having a second bandwidth that is less than the first bandwidth of the first envelope signal E1. The second envelope signal E2 may sometimes be referred to as a bandwidth reduced envelope signal. The bandwidth reduction block may be configured to optimize or maximum the amplitude of the second envelope signal E2 under the constraints that the second bandwidth is less than the first bandwidth and that the target load signal does not saturate the load shaping block 82.

During the operations of block 114, envelope shaping circuit 74 can generate an envelope tracking (ET) control signal based on the bandwidth reduced envelope signal E2. During the operations of block 116, envelope tracker 76 can generate power supply voltage Vcc as a function of the ET control signal. The power supply voltage Vec can be fed to the power supply terminal of radio-frequency amplifier 50.

During the operations of block 118, the load modulation circuitry can generate, with inverse amplifier gain model 80, a target load signal as a function of the baseband signal received from processor(s) 26 and the bandwidth reduced envelope signal E2. The target load signal computed by the inverse amplifier gain model 80 may be dynamically tuned to ensure that the instantaneous amplifier gain is constant when amplifier 50 is operated with the current baseband signal and supplied with voltage Vcc generated based on the current bandwidth reduced envelope signal E2 (e.g., the target load signal can ensure that amplifier 50 is operating in compression mode in a subrange of instantaneous amplifier output power levels). Inverse gain model 80 may also be a function of the target amplifier output power level.

During the operations of block 120, load shaping block 82 can generate a load control signal as a function of the target load signal. For example, load shaping block 82 may be configured to map the internal algorithmic target load signal to a physical load control signal that directly tunes adjustable load Z_{L}. The example of FIG. 6 in which blocks 118 and 120 are shown as occurring after blocks 114 and 116 is merely illustrative. If desired, the operations of blocks 118 and 120 can occur simultaneously with or before the operations of blocks 114 and 116.

During the operations of block 122, the Vcc generated from block 116 and the load control signal generated from block 120 can be fed as control signals to radio-frequency amplifier 50. Configured and operated in this way, the efficiency of amplifier 50 can be optimized while reducing the bandwidth requirements for the envelope tracking supply modulation path.

The methods and operations described above in connection with FIGS. 1-6 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Wireless circuitry comprising:
a radio-frequency amplifier configured to receive a radio-frequency signal generated from a baseband signal;
supply modulation circuitry configured to output a power supply voltage, derived from the baseband signal, for powering the radio-frequency amplifier and to output an envelope signal; and
load modulation circuitry configured to output a load control signal, derived from the baseband signal and the envelope signal, for tuning an adjustable load component of the radio-frequency amplifier.

2. The wireless circuitry of claim 1, wherein the supply modulation circuitry comprises:
a first envelope generator configured to output a target envelope signal, associated with the baseband signal, having a first bandwidth.

3. The wireless circuitry of claim 2, wherein the supply modulation circuitry further comprises:
a second envelope generator configured to receive the target envelope signal and to output the envelope signal having a second bandwidth that is less than the first bandwidth.

4. The wireless circuitry of claim 3, wherein the supply modulation circuitry further comprises:
an envelope shaping circuit configured to receive the envelope signal from the second envelope generator and map the envelope signal to a corresponding envelope tracking control signal.

5. The wireless circuitry of claim 4, wherein the supply modulation circuitry further comprises:
an envelope tracking circuit configured to receive the envelope tracking control signal from the envelope shaping circuit and output the power supply voltage to a power supply terminal of the radio-frequency amplifier.

6. The wireless circuitry of claim 3, wherein the load modulation circuitry is configured to generate a target load signal based on an inverse amplifier gain model that is a function of the baseband signal and the envelope signal.

7. The wireless circuitry of claim 6, wherein the load modulation circuitry further comprises:
a load shaping circuit configured to receive the target load signal and generate the load control signal based on the target load signal.

8. The wireless circuitry of claim 7, wherein the second envelope generator comprises a bandwidth reduction circuit configured to increase the envelope signal and ensure that the target load signal does not saturate the load shaping circuit.

9. The wireless circuitry of claim 6, wherein the load modulation circuitry is further configured to generate the target load signal based on the inverse amplifier gain model to ensure that an instantaneous gain of the radio-frequency amplifier is maintained at a substantially constant level.

10. The wireless circuitry of claim 6, wherein the load modulation circuitry is further configured to generate the target load signal based on the inverse amplifier gain model to ensure that the radio-frequency amplifier is operated in a compression mode in a subrange of instantaneous output power levels of the radio-frequency amplifier.

11. A method of operating wireless circuitry, comprising:
with a radio-frequency amplifier, receiving a radio-frequency signal generated from a baseband signal;
with supply modulation circuitry, outputting an envelope signal and outputting a power supply voltage derived from the baseband signal to a power supply terminal of the radio-frequency amplifier;
with load modulation circuitry, outputting a load control signal derived from the baseband signal and the envelope signal; and
tuning an adjustable load component of the radio-frequency amplifier based on the load control signal.

12. The method of claim 11, further comprising:
with the supply modulation circuitry, generating a target envelope signal from the baseband signal, wherein the target envelope signal has a first bandwidth and wherein the envelope signal has a second bandwidth less than the first bandwidth.

13. The method of claim 12, further comprising:
with the supply modulation circuitry, generating an envelope tracking control signal from the envelope signal and generating the power supply voltage as a function of the envelope tracking control signal.

14. The method of claim 11, further comprising:
with the load modulation circuitry, generating a target load signal based on an inverse amplifier gain model that is a function of the baseband signal and the envelope signal.

15. The method of claim 14, further comprising:
with a load shaping block in the load modulation circuitry, generating the load control signal as a function of the target load signal; and
increasing the envelope signal while ensuring that the target load signal does not saturate the load shaping block.

16. Wireless circuitry comprising:
a radio-frequency amplifier configured to receive a radio-frequency signal generated from a baseband signal;
a first envelope generation block configured to receive the baseband signal and to output a first envelope signal having a first bandwidth; and
a second envelope generation block configured to receive the first envelope signal and to output a second envelope signal having a second bandwidth different than the first bandwidth.

17. The wireless circuitry of claim 16, wherein the second envelope generation block comprises a bandwidth reduction block configured to output the second envelope signal such that the second bandwidth of the second envelope signal is less than the first bandwidth of the first envelope signal.

18. The wireless circuitry of claim 16, further comprising:
one or more blocks configured to generate a power supply voltage as a function of the second envelope signal, wherein the power supply voltage is provided to a power supply terminal of the radio-frequency amplifier.

19. The wireless circuitry of claim 16, further comprising:
one or more load modulation blocks configured to receive the baseband signal and the second envelope signal and generate a corresponding load control signal for tuning an adjustable load component of the radio-frequency amplifier.

20. The wireless circuitry of claim 19, wherein the one or more load modulation blocks are further configured to generate a target load signal based on an inverse amplifier gain model that is a function of the baseband signal and the second envelope signal, and wherein the one or more load modulation blocks include a load shaping block configured to receive the target load signal and to generate the load control signal based on the received target load signal.
